(19) United States
(12) Patent Application Publication
(10) Pub. No.: US 2026/0198092 A1
(43) Pub. Date: Jul. 9, 2026

(54) DISPLAY APPARATUS INCLUDING STACKED CAPACITOR STRUCTURE AND ELECTRONIC APPARATUS INCLUDING THE SAME

(71) Applicant: SAMSUNG DISPLAY CO., LTD., YONGIN-SI (KR)

(72) Inventors: Taeho Kim, YONGIN-SI (KR); Seungjun Lee, YONGIN-SI (KR); Gunhee Kim, YONGIN-SI (KR); Jaewoo Lee, YONGIN-SI (KR); Joohee Jeon, YONGIN-SI (KR); Sunyoung Jung, YONGIN-SI (KR)

(21) Appl. No.: 19/421,056

(22) Filed: Dec. 16, 2025

(30) Foreign Application Priority Data
Jan. 9, 2025 (KR) 10-2025-0003726

(51) Int. Cl. H10D 86/40; H10D 86/60; H10H 29/01; H10H 29/32; H10H 29/49

(52) U.S. Cl. CPC H10D 86/481; H10D 86/423; H10D 86/60; H10H 29/012; H10H 29/32; H10H 29/49

(57) ABSTRACT

A display includes a first semiconductor pattern including a first capacitor electrode, a first capacitor including the first capacitor electrode and a second capacitor electrode disposed on the first capacitor electrode. A second capacitor includes a lower capacitor including the second capacitor electrode and a third capacitor electrode disposed on the second capacitor electrode, and an upper capacitor including the third capacitor electrode and a fourth capacitor electrode disposed on the third capacitor electrode. A second semiconductor pattern is disposed on the fourth capacitor electrode and includes a driving semiconductor layer, and a driving transistor including the driving semiconductor layer and a driving gate electrode disposed on the driving semiconductor layer.

### CROSS-REFERENCE TO RELATED APPLICATION

This application is based on and claims priority under 35 U.S.C. §119 to Korean Patent Application No. 10-2025-0003726, filed on January 9, 2025, in the Korean Intellectual Property Office, the disclosure of which is incorporated by reference herein in its entirety.

### TECHNICAL FIELD

The present disclosure relates to a display apparatus and, more specifically, to a display apparatus including a stacked capacitor structure and an electronic apparatus including the same.

### DISCUSSION OF THE RELATED ART

As display technology continues to advance rapidly, new types of display devices are being developed that offer improved features, such as reduced thickness, lighter weight, and lower power consumption.

These display devices may be liquid crystal display (LCD) apparatus that rely upon a backlight to produce light, or may be a light-emitting display apparatus including a display element capable of emitting light. The light-emitting display apparatus may include display elements having an emission layer.

### SUMMARY

A display apparatus includes a first semiconductor pattern including a first capacitor electrode, a first capacitor including the first capacitor electrode and a second capacitor electrode disposed on the first capacitor electrode, and a second capacitor including a lower capacitor including the second capacitor electrode and a third capacitor electrode disposed on the second capacitor electrode, and an upper capacitor including the third capacitor electrode and a fourth capacitor electrode disposed on the third capacitor electrode. The display apparatus further includes a second semiconductor pattern disposed on the fourth capacitor electrode and including a driving semiconductor layer, and a driving transistor including the driving semiconductor layer and a driving gate electrode disposed on the driving semiconductor layer.

At least a portion of the driving transistor may overlap each of the first capacitor and the second capacitor.

Each of the second capacitor electrode and the fourth capacitor electrode may be electrically connected to the driving semiconductor layer.

The first capacitor electrode may be electrically connected to the driving gate electrode, and the second capacitor electrode may be electrically connected to the driving semiconductor layer.

The display apparatus may further include a first connection electrode disposed on the driving gate electrode and electrically connecting the first capacitor electrode and the driving gate electrode to each other, and a second connection electrode disposed on the driving gate electrode and electrically connecting the second capacitor electrode and the driving semiconductor layer to each other.

The display apparatus may further include a driving voltage line carrying a driving voltage, and the third capacitor electrode may be electrically connected to the driving voltage line.

The second capacitor electrode may be electrically connected to the driving semiconductor layer, and the third capacitor electrode may be electrically connected to the driving gate electrode.

The display apparatus may further include a driving voltage line carrying a driving voltage, and the first capacitor electrode may be electrically connected to the driving voltage line.

The display apparatus may further include an emission control line which sharing a layer with the second capacitor electrode and including an emission control gate electrode, and an emission control transistor including an emission control semiconductor layer included in the first semiconductor pattern and the emission control gate electrode.

The display apparatus may further include a light-emitting diode electrically connected to the emission control transistor.

The first semiconductor pattern may include a silicon semiconductor material, and the second semiconductor pattern may include an oxide semiconductor material.

A display apparatus includes an emission control transistor including an emission control semiconductor layer and an emission control gate electrode disposed on the emission control semiconductor layer, a first capacitor including a first capacitor electrode in a same layer as the emission control semiconductor layer and a second capacitor electrode disposed on the first capacitor electrode, and a second capacitor including a lower capacitor including the second capacitor electrode and a third capacitor electrode disposed on the second capacitor electrode and an upper capacitor including the third capacitor electrode and a fourth capacitor electrode disposed on the third capacitor electrode. The display apparatus further includes a driving transistor including a driving semiconductor layer disposed on the fourth capacitor electrode and a driving gate electrode disposed on the driving semiconductor layer. Each of the first capacitor and the second capacitor overlaps at least a portion of the driving transistor.

Each of the second capacitor electrode and the fourth capacitor electrode may be electrically connected to the driving semiconductor layer.

The first capacitor electrode may be electrically connected to the driving gate electrode, and the second capacitor electrode may be electrically connected to the driving semiconductor layer.

The display apparatus may further include a first connection electrode disposed on the driving gate electrode and electrically connecting the first capacitor electrode and the driving gate electrode to each other, and a second connection electrode disposed on the driving gate electrode and electrically connecting the second capacitor electrode and the driving semiconductor layer to each other.

The display apparatus may further include a driving voltage line carrying a driving voltage, and the third capacitor electrode may be electrically connected to the driving voltage line.

The second capacitor electrode may be electrically connected to the driving semiconductor layer, and the third capacitor electrode may be electrically connected to the driving gate electrode.

The display apparatus may further include a driving voltage line carrying a driving voltage, and the first capacitor electrode may be electrically connected to the driving voltage line.

The display apparatus may further include a data write transistor including a data write semiconductor layer which is in a same layer as the driving semiconductor layer and a data write gate electrode disposed on the data write semiconductor layer, and a data line carrying a data signal to the data write transistor. The data write transistor may be electrically connected to the driving transistor.

The emission control semiconductor layer may include a silicon semiconductor material, and the driving semiconductor layer may include an oxide semiconductor material.

An electronic apparatus includes a display apparatus. The display apparatus includes a first semiconductor pattern including a first capacitor electrode, a first capacitor including the first capacitor electrode and a second capacitor electrode disposed on the first capacitor electrode, and a second capacitor including a lower capacitor including the second capacitor electrode and a third capacitor electrode disposed on the second capacitor electrode and an upper capacitor including the third capacitor electrode and a fourth capacitor electrode disposed on the third capacitor electrode. The electronic apparatus further includes a second semiconductor pattern disposed on the fourth capacitor electrode and including a driving semiconductor layer. A driving transistor includes the driving semiconductor layer and a driving gate electrode disposed on the driving semiconductor layer.

The electronic apparatus may further include a display module, a processor, a power module, and a memory, and the display apparatus may include at least one of the display module, the processor, the power module, or the memory.

### BRIEF DESCRIPTION OF THE DRAWINGS

The above and other aspects and feature of certain embodiments of the disclosure will be more apparent from the following description taken in conjunction with the accompanying drawings, in which:

FIG. 1 is a plan view schematically illustrating a display apparatus according to an embodiment;

FIG. 2 is an equivalent circuit diagram schematically illustrating a light-emitting diode of one pixel of a display apparatus according to an embodiment and a pixel circuit electrically connected to the light-emitting diode;

FIG. 3 is a cross-sectional view illustrating a portion of a display apparatus according to an embodiment;

FIG. 4 is a plan view illustrating a portion of a pixel circuit of a display apparatus according to an embodiment;

FIGS. 5 to 12 are plan views illustrating a process of forming a pixel circuit included in a display apparatus according to an embodiment;

FIG. 13 is a cross-sectional view schematically illustrating a display apparatus according to an embodiment;

FIG. 14 is a block diagram of an electronic apparatus according to an embodiment; and

FIG. 15 are schematic views of an electronic apparatus according to various embodiments.

### DETAILED DESCRIPTION

Reference will now be made in detail to embodiments, examples of which are illustrated in the accompanying drawings, wherein like reference numerals may refer to like elements throughout the specification and the figures. In this regard, the present embodiments may have different forms and should not necessarily be construed as being limited to the descriptions set forth herein. Accordingly, the embodiments are described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not necessarily by being limited to the embodiments presented below.

Hereinafter, embodiments of the present disclosure will be described in detail with reference to the accompanying drawings, and in the description with reference to the drawings, the same or corresponding components are indicated by the same reference numerals and to the extent that an element is not described in detail with respect to this figure, it may be understood that the element is at least similar to a corresponding element that has been described elsewhere within the present disclosure.

In the following embodiment, it will be understood that although the terms "first," "second," etc. may be used herein to describe various components, these components should not necessarily be limited by these terms. These terms are used to distinguish one component from another.

In the following embodiment, the expression of singularity in the present specification includes the expression of plurality unless clearly specified otherwise in context.

In the following embodiment, it will be further understood that the terms "comprises" and/or "comprising" used herein specify the presence of stated features or components, but do not preclude the presence or addition of one or more other features or components.

In the following embodiment, it will be understood that when a layer, area, or component is referred to as being "formed on" another layer, area, or component, it can be directly or indirectly formed on the other layer, area, or component. For example, intervening layers, areas, or components may be present.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When a certain embodiment may be implemented differently, a specific process order may be performed differently from the described order. For example, two consecutively described processes may be performed substantially at the same time or performed in an order opposite to the described order.

In the present specification, the expression "A and/or B" represents A, B, or A and B. In addition, the expression "at least one of A and B" or "at least one of A or B" represents A, B, or A and B.

It will be understood that when a layer, area, or component is referred to as being "connected to" another layer, area, or component, it can be directly or indirectly connected to the other layer, area, or component. For example, intervening layers, areas, or components may be present. For example, in the present specification, when a layer, area, or component is electrically connected to another layer, area, or component, the layers, areas, or components might not only be directly electrically connected, but may also be indirectly electrically connected via another layer, area, or component therebetween.

The x-axis, the y-axis, and the z-axis are not necessarily limited to three axes of the Cartesian rectangular coordinate system, and may be interpreted in a broader sense. For example, the x-axis, the y-axis, and the z-axis may be perpendicular to one another, or may represent different directions that are not perpendicular to one another.

Embodiments of the present disclosure relate to the use of a sophisticated multilayer capacitor structure integrated into a display apparatus to improve image quality and optimize space utilization within each pixel. This design includes overlapping capacitors, such as a storage capacitor and a holding capacitor, that are stacked vertically rather than spread out across the substrate. By arranging these components in the z-axis direction, the invention significantly reduces the planar area occupied by each pixel circuit, thereby increasing pixel density and enhancing resolution in the display apparatus.

For example, a display apparatus includes a vertically stacked arrangement of a storage capacitor (Cst) and a holding capacitor (Chold), which includes two sub-capacitors (Chold1 and Chold2). This vertical stacking increases pixel density and thereby enhances the resolution of the display.

Moreover, an oxide semiconductor layer in the driving transistor allows for beneficial electrical properties, particularly stability and performance in high-resolution displays. The layering of multiple capacitor electrodes (CE1 through CE4) and the integration of a driving transistor (T1) above this multilayer stack allow for compact, high-performance pixel circuits that maximize the use of vertical space.

Thus, multiple capacitor electrodes are arranged in distinct layers, where each layer is fabricated from conductive or semiconductive materials and separated by insulating layers. The overlapping design allows for both capacitors to share intermediate electrodes, minimizing material use and simplifying electrical connectivity. A driving transistor is situated above the multilayer capacitor assembly, with key portions overlapping both capacitors. The configuration facilitates precise control of image signal processing by improving voltage stability and reducing luminance variation across the display.

Additionally, embodiments of the present disclosure may employ both silicon-based and oxide-based semiconductor materials in specific transistor layers to optimize performance characteristics such as switching speed, current control, and light emission regulation. This architecture is especially beneficial for applications in OLED displays used in a wide array of electronic devices, from smartphones and wearables to vehicle displays and larger format screens.

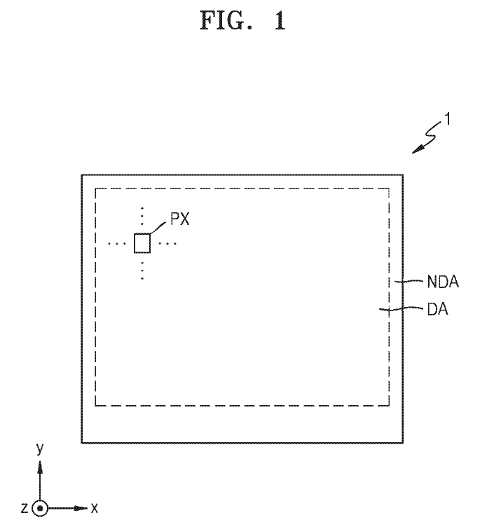

FIG. 1 is a plan view schematically illustrating a display apparatus according to an embodiment.

Referring to FIG. 1, a display apparatus 1 may include a display area DA that displays an image and a non-display area NDA outside the display area DA. The display area DA may be partially or entirely surrounded by the non-display area NDA. For example, the non-display area NDA may be adjacent to one side of the display area DA, may surround the display area DA on two opposing sides, may surround the display area DA on three sides, or may fully surround the display area DA on all sides.

A plurality of pixels PX may be disposed in the display area DA. The plurality of pixels PX might not be disposed in the non-display area NDA. Each of the pixels PX may include a display element, such as an organic light-emitting diode, and a pixel circuit electrically connected to the display element. Each pixel PX may emit, for example, red light, green light, blue light, or white light.

In an embodiment, the display area DA may have a rectangular shape in a plan view. In an embodiment, the display area DA may have a polygonal shape such as a triangle, a pentagon, or a hexagon, or may have a circular shape, an elliptical shape, or an irregular shape. In an embodiment, the display area DA may be an otherwise polygonal shape but with rounded corners.

The display apparatus 1 displays a moving image or a still image and may be used in a portable electronic device, such as a mobile phone, a smartphone, a tablet computer, a laptop/notebook computer, a mobile communication terminal, an electronic notebook, an e-book, a portable multimedia player (PMP), a navigation device, or an ultra-mobile PC (UMPC). Alternatively, the display apparatus 1 may be used in a television, a computer monitor, a digital billboard, and an electronic device of the Internet of Things (IoT), or may be used in a wearable electronic device such as a smart watch, a watch phone, a glasses-type display, and a head-mounted display (HMD). In addition, the display apparatus 1, according to an embodiment, may be used in an instrument panel of a vehicle, a center information display (CID) disposed on the center fascia or dashboard of a vehicle, a room mirror display in place of side-view mirrors of a vehicle, or an electronic device for display disposed at the rear side of a front seat as an entertainment for a rear seat of a vehicle.

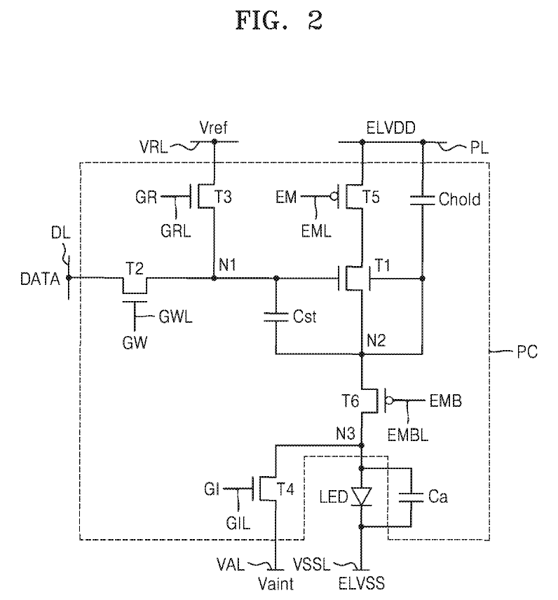

FIG. 2 is an equivalent circuit diagram schematically illustrating a light-emitting diode of one pixel of a display apparatus according to an embodiment and a pixel circuit electrically connected to the light-emitting diode.

A pixel circuit PC may be electrically connected to a first gate line GWL carrying a first gate signal GW, a second gate line GRL carrying a second gate signal GR, a third gate line EML carrying a third gate signal EM, a fourth gate line GIL carrying a fourth gate signal GI, a fifth gate line EMBL carrying a fifth gate signal EMB, and a data line DL carrying a data signal DATA. Light emission of a light-emitting diode LED is controlled by the third gate signal EM and the fifth gate signal EMB, and thus, the third gate signal EM and the fifth gate signal EMB are emission control signals, and the third gate line EML and the fifth gate line EMBL may be referred to as emission control lines. The pixel circuit PC may be electrically connected to a driving voltage line PL carrying a driving voltage ELVDD, a reference voltage line VRL carrying a reference voltage Vref, and an initialization voltage line VAL carrying an initialization voltage Vaint.

In an embodiment, some of a plurality of transistors included in the pixel circuit PC may be N-type transistors, while the others may be P-type transistors. First to fourth transistors T1, T2, T3, and T4 may be N-type transistors, and fifth and sixth transistors T5 and T6 may be P-type transistors. A semiconductor layer of each of the first to fourth transistors T1, T2, T3, and T4 may include a different material from a semiconductor layer of each of the fifth and sixth transistors T5 and T6. In some embodiments, the first to fourth transistors T1, T2, T3, and T4 may include an oxide semiconductor material, while the fifth and sixth transistors T5 and T6 may include amorphous silicon, polysilicon, or an organic semiconductor.

The pixel circuit PC may include the first to sixth transistors T1, T2, T3, T4, T5, and T6, a storage capacitor Cst, a holding capacitor Chold, and an auxiliary capacitor Ca. The first transistor T1 may be a driving transistor configured to output a driving current corresponding to the data signal DATA, and the second to sixth transistors T2, T3, T4, T5, and T6 may be switching transistors carrying various signals. The first transistor T1 may be referred to as a driving transistor, the second transistor T2 may be referred to as a data write transistor, the third transistor T3 may be referred to as a compensation transistor, the fourth transistor T4 may be referred to as an initialization transistor, the fifth transistor T5 may be referred to as an operation control transistor, and the sixth transistor T6 may be referred to as an emission control transistor.

A first terminal (or a first electrode) and a second terminal (or a second electrode) of each of the first to sixth transistors T1, T2, T3, T4, T5, and T6 may be a source (or a source electrode) or a drain (or a drain electrode) according to voltages of the first terminal and the second terminal. For example, according to the voltages of the first terminal and the second terminal, the first terminal may be a drain and the second terminal may be a source, or the first terminal may be a source and the second terminal may be a drain. Hereinafter, a node to which a first-1 gate electrode of the first transistor T1 is connected may be defined as a first node N1, and a node to which the second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a first gate (or a first gate electrode), the first terminal, and the second terminal connected to the second node N2. The first transistor T1 may include a first-1 gate connected to the first node N1. The first transistor T1 may further include a first-2 gate connected to its second terminal. The first-1 gate and the first-2 gate may face each other on different layers. For example, the first-1 gate and the first-2 gate of the first transistor T1 may face each other with the semiconductor layer interposed therebetween. Throughout the present specification, the first gate (or the first gate electrode) of the first transistor T1 may refer to the first-1 gate (or the first-1 gate electrode) that is involved in turning on or turning off the first transistor T1.

A gate (or the first-1 gate) of the first transistor T1 may be connected to the second terminal of the second transistor T2, the first terminal of the third transistor T3, and the storage capacitor Cst. The first-2 gate of the first transistor T1 may be connected to the first terminal of the sixth transistor T6, the storage capacitor Cst, and the holding capacitor Chold. The first terminal of the first transistor T1 may be connected to the driving voltage line PL via the fifth transistor T5, and the second terminal of the first transistor T1 may be connected to a pixel electrode of the light-emitting diode LED via the sixth transistor T6. The first terminal of the first transistor T1 may be connected to the second terminal of the fifth transistor T5. The second terminal of the first transistor T1 may be connected to the first terminal of the sixth transistor T6, the storage capacitor Cst, and the holding capacitor Chold. The first transistor T1 may be configured to receive the data signal DATA according to a switching operation of the second transistor T2 and control the amount of driving current flowing to the light-emitting diode LED.

The second transistor T2 may be connected to the data line DL and the gate of the first transistor T1. The second transistor T2 may include a gate connected to the first gate line GWL, the first terminal connected to the data line DL, and the second terminal connected to the first node N1. The second terminal of the second transistor T2 may be connected to the gate of the first transistor T1, the first terminal of the third transistor T3, and the storage capacitor Cst. The second transistor T2 may be turned on by the first gate signal GW transmitted via the first gate line GWL to electrically connect the data line DL and the first node N1 to each other, and may be carrying the data signal DATA transmitted via the data line DL to the first node N1.

The third transistor T3 may be connected to the gate of the first transistor T1 and the reference voltage line VRL. The third transistor T3 may include a gate connected to the second gate line GRL, the first terminal connected to the first node N1, and the second terminal connected to the reference voltage line VRL. The first terminal of the third transistor T3 may be connected to the gate of the first transistor T1, the second terminal of the second transistor T2, and the storage capacitor Cst. The third transistor T3 may be turned on by the second gate signal GR transmitted via the second gate line GRL to transmit the reference voltage Vref transmitted via the reference voltage line VRL to the first node N1.

The fourth transistor T4 may be connected to the sixth transistor T6 and the initialization voltage line VAL. The fourth transistor T4 may be connected between the light-emitting diode LED and the initialization voltage line VAL. The fourth transistor T4 may include a gate connected to the fourth gate line GIL, the first terminal connected to a third node N3, and the second terminal connected to the initialization voltage line VAL. The first terminal of the fourth transistor T4 may be connected to the second terminal of the sixth transistor T6 and the pixel electrode of the light-emitting diode LED. The fourth transistor T4 may be turned on by the fourth gate signal GI transmitted via the fourth gate line GIL to transmit the initialization voltage Vaint transmitted via the initialization voltage line VAL to the third node N3 and initialize the pixel electrode (for example, an anode) of the light-emitting diode LED.

The fifth transistor T5 may be connected to the driving voltage line PL and the first transistor T1. The fifth transistor T5 may include a gate connected to the third gate line EML, the first terminal connected to the driving voltage line PL, and the second terminal connected to the first terminal of the first transistor T1. The fifth transistor T5 may be turned on or turned off according to the third gate signal EM transmitted via the third gate line EML.

The sixth transistor T6 may be connected to the first transistor T1 and the light-emitting diode LED. The sixth transistor T6 may be connected between the second node N2 and the third node N3. The sixth transistor T6 may include a gate connected to the fifth gate line EMBL, the first terminal connected to the second node N2, and the second terminal connected to the third node N3. The first terminal of the sixth transistor T6 may be connected to the second terminal of the first transistor T1, the storage capacitor Cst, and the holding capacitor Chold. The second terminal of the sixth transistor T6 may be connected to the first terminal of the fourth transistor T4 and the pixel electrode of the light-emitting diode LED. The sixth transistor T6 may be turned on or turned off according to the fifth gate signal EMB transmitted via the fifth gate line EMBL.

The storage capacitor Cst may be connected between the gate of the first transistor T1 and the second terminal of the first transistor T1. A first electrode of the storage capacitor Cst may be connected to the first node N1, and a second electrode of the storage capacitor Cst may be connected to the second node N2. The first electrode of the storage capacitor Cst may be connected to the gate of the first transistor T1, the second terminal of the second transistor T2, and the first terminal of the third transistor T3. The second electrode of the storage capacitor Cst may be connected to the second terminal and the first-2 gate of the first transistor T1, a second electrode of the holding capacitor Chold, and the first terminal of the sixth transistor T6. The storage capacitor Cst is a storage capacitor and may store a voltage corresponding to a threshold voltage of the first transistor T1 and the data signal DATA.

When the third transistor T3 and the fifth transistor T5 are turned on, the first transistor T1 may be turned on. When a voltage of the second terminal of the first transistor T1 drops to a difference (Vref-Vth1) between the reference voltage Vref and a threshold voltage (Vth1) of the first transistor T1, the first transistor T1 may be turned off, and the storage capacitor Cst may store a voltage corresponding to the threshold voltage (Vth1) of the first transistor T1 to compensate for the threshold voltage (Vth1) of the first transistor T1.

The holding capacitor Chold may be connected between the driving voltage line PL and the second node N2. A first electrode of the holding capacitor Chold may be connected to the driving voltage line PL. The second electrode of the holding capacitor Chold may be connected to the second terminal and the first-2 gate of the first transistor T1, the second electrode of the storage capacitor Cst, and the first terminal of the sixth transistor T6.

A capacitance of each of the storage capacitor Cst and the holding capacitor Chold may vary depending on a color of light emitted from the light-emitting diode LED.

The auxiliary capacitor Ca may be electrically connected to the sixth transistor T6, a sustain voltage line VSSL, and the pixel electrode of the light-emitting diode LED. The auxiliary capacitor Ca may store and maintain a voltage corresponding to a voltage difference between the pixel electrode of the light-emitting diode LED and the sustain voltage line VSSL, thereby preventing an increase in black luminance when the sixth transistor T6 is turned off.

The light-emitting diode LED may be connected to the first transistor T1 via the sixth transistor T6. The light-emitting diode LED includes the pixel electrode (e.g., the anode) connected to the third node N3 and an opposite electrode (e.g., a cathode) facing the pixel electrode, wherein the opposite electrode may receive a common voltage ELVSS. In an embodiment, the opposite electrode (e.g., the cathode) may extend into a display area DA and be electrically connected to the sustain voltage line VSSL that provides the common voltage ELVSS. A driving current output by the first transistor T1 may flow through the light-emitting diode LED by the turned-on fifth transistor T5 and the turned-on sixth transistor T6, and the light-emitting diode LED may emit light with a luminance corresponding to the magnitude of the driving current.

FIG. 2 illustrates that the pixel circuit PC includes six transistors, but the disclosure is not necessarily limited thereto. In an embodiment, the pixel circuit PC may include seven transistors. In an embodiment, the number of transistors in the pixel circuit PC may be five or less or may be eight or more.

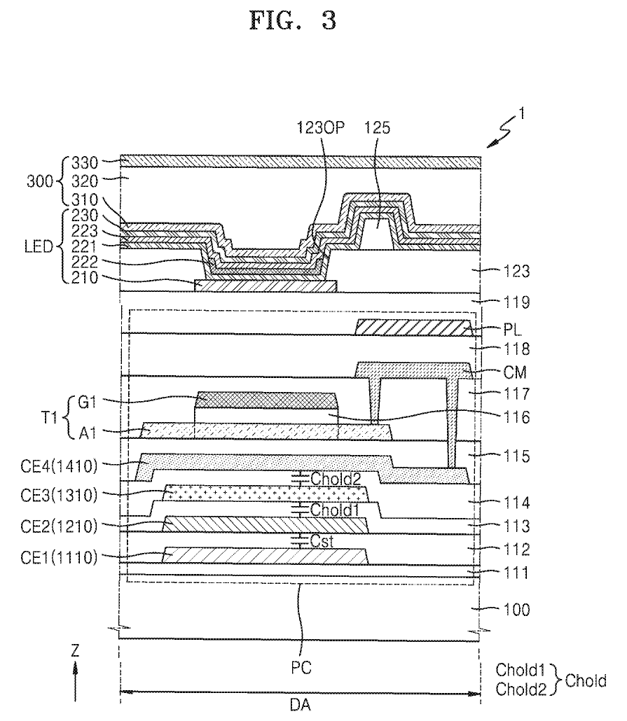

FIG. 3 is a cross-sectional view illustrating a portion of a display apparatus according to an embodiment.

Referring to FIG. 3, the display apparatus 1 may include a substrate 100, the light-emitting diode LED disposed on the substrate 100, and the pixel circuit PC electrically connected to the light-emitting diode LED. The display apparatus 1 may include the light-emitting diode LED disposed in the display area DA. The pixel circuit PC may be disposed between the substrate 100 and the light-emitting diode LED. In an embodiment, FIG. 3 illustrates the first transistor T1, the storage capacitor Cst, and the holding capacitor Chold as some components of the pixel circuit PC.

The substrate 100 may include a glass material or polymer resin. In an embodiment, the substrate 100 may have a structure in which a base layer including polymer resin and a barrier layer including an inorganic insulating material such as silicon oxide or silicon nitride are alternately stacked. Polymer resin may include at least one of polyethersulfone, polyarylate, polyether imide, polyethylene naphthalate, polyethylene terephthalate, polyphenylene sulfide, polyimide, polycarbonate, cellulose triacetate, or cellulose acetate propionate, etc.

A first capacitor electrode CE1, a second capacitor electrode CE2, a third capacitor electrode CE3, and a fourth capacitor electrode CE4 may be disposed on the substrate 100. For example, the first capacitor electrode CE1 may be disposed on the substrate 100, the second capacitor electrode CE2 may be disposed on the first capacitor electrode CE1, the third capacitor electrode CE3 may be disposed on the second capacitor electrode CE2, and the fourth capacitor electrode CE4 may be disposed on the third capacitor electrode CE3.

In an embodiment, the storage capacitor Cst may be disposed on the substrate 100. The storage capacitor Cst may include the first capacitor electrode CE1 and the second capacitor electrode CE2. For example, the storage capacitor Cst may be disposed on a buffer layer 111.

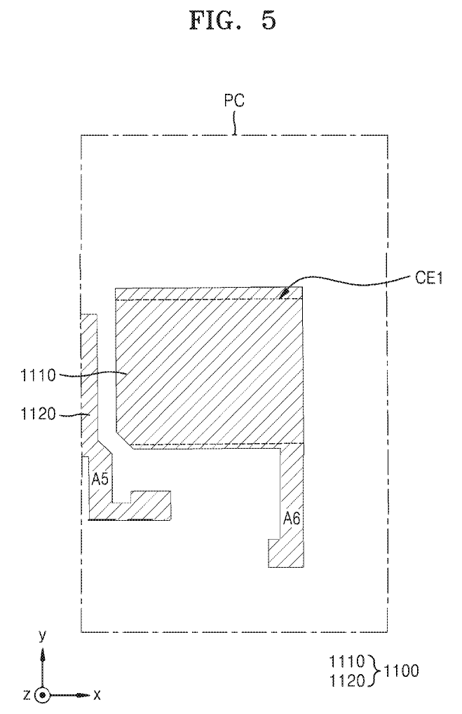

The first capacitor electrode CE1 may be a portion of a first semiconductor pattern 1110 described below with reference to FIG. 5. For example, the first capacitor electrode CE1 may include a silicon semiconductor material. For example, the first capacitor electrode CE1 may include amorphous silicon or may include polysilicon. For example, the first capacitor electrode CE1 may include polysilicon crystallized at low temperature.

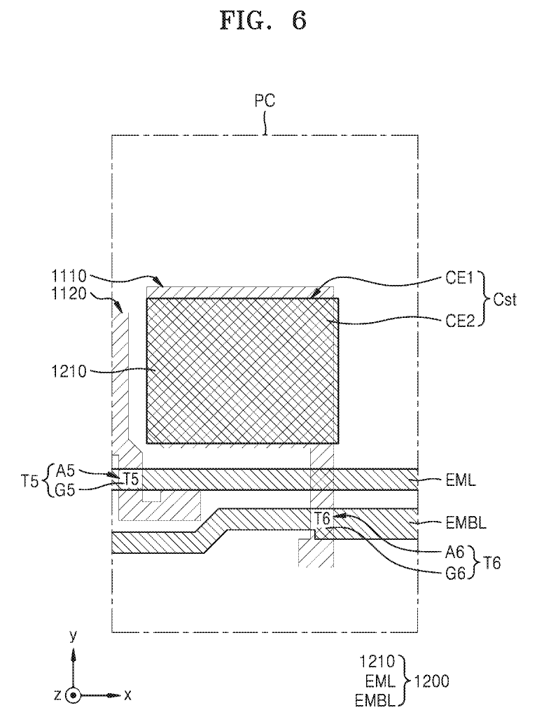

The second capacitor electrode CE2 may be at least a portion of a first conductive pattern 1210 described below with reference to FIG. 6. The second capacitor electrode CE2 may include a conductive material, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

In an embodiment, the holding capacitor Chold may be disposed on the storage capacitor Cst. The holding capacitor Chold may overlap the storage capacitor Cst. In an embodiment, the holding capacitor Chold may include a first holding capacitor Chold1 and a second holding capacitor Chold2 that overlap each other in a direction (for example, a z direction) perpendicular to a top surface of the substrate 100. For example, each of the first holding capacitor Chold1 and the second holding capacitor Chold2 may overlap the storage capacitor Cst. The first holding capacitor Chold1 may be referred to as a lower holding capacitor, and the second holding capacitor Chold2 may be referred to as an upper holding capacitor.

In an embodiment, the first holding capacitor Chold1 may include the second capacitor electrode CE2 and the third capacitor electrode CE3. For example, the second capacitor electrode CE2 may function as one electrode of the storage capacitor Cst and simultaneously may function as one electrode of the first holding capacitor Chold1.

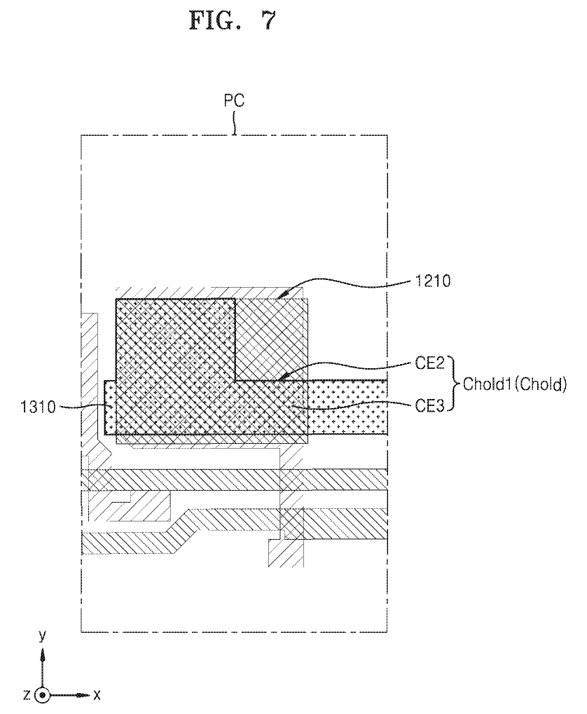

The third capacitor electrode CE3 may be at least a portion of a second conductive pattern 1310 described below with reference to FIG. 7. The third capacitor electrode CE3 may include a conductive material, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

In an embodiment, the second holding capacitor Chold2 may include the third capacitor electrode CE3 and the fourth capacitor electrode CE4. For example, the first holding capacitor Chold1 and the second holding capacitor Chold2 may share the third capacitor electrode CE3.

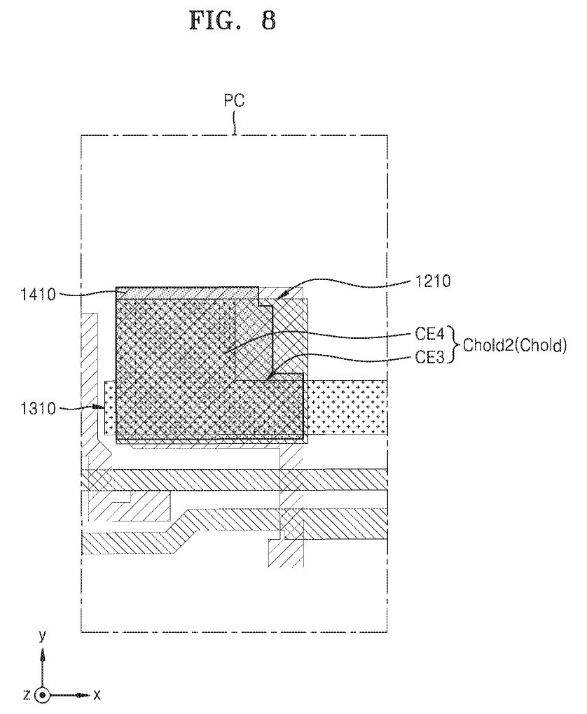

The fourth capacitor electrode CE4 may be at least a portion of a third conductive pattern 1410 described below with reference to FIG. 8. The fourth capacitor electrode CE4 may include a conductive material, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

The buffer layer 111 may be disposed on the substrate 100. For example, the buffer layer 111 may be disposed between the substrate 100 and the storage capacitor Cst. For example, the buffer layer 111 may be disposed between the substrate 100 and the first capacitor electrode CE1. The buffer layer 111 may be an inorganic insulating layer including an inorganic insulating material such as silicon nitride and/or silicon oxide, and may have a single-layered or multilayer structure including the above-described material.

A first insulating layer 112 may be disposed on the first capacitor electrode CE1. For example, the first insulating layer 112 may be disposed between the first capacitor electrode CE1 and the second capacitor electrode CE2. A second insulating layer 113 may be disposed on the second capacitor electrode CE2. For example, the second insulating layer 113 may be disposed between the second capacitor electrode CE2 and the third capacitor electrode CE3. A third insulating layer 114 may be disposed on the third capacitor electrode CE3. For example, the third insulating layer 114 may be disposed between the third capacitor electrode CE3 and the fourth capacitor electrode CE4. A fourth insulating layer 115 may be disposed on the fourth capacitor electrode CE4. For example, the fourth insulating layer 115 may be disposed between the fourth capacitor electrode CE4 and a driving semiconductor layer A1 of the first transistor T1 described below.

Each of the first insulating layer 112, the second insulating layer 113, the third insulating layer 114, and the fourth insulating layer 115 may include, for example, an inorganic insulating material such as silicon oxide, silicon nitride, or silicon oxynitride, and may have a single-layered or multilayer structure including the above-described inorganic insulating material.

The first transistor T1 may be disposed on the holding capacitor Chold. The first transistor T1 may overlap the storage capacitor Cst. The first transistor T1 may overlap the holding capacitor Chold. For example, at least a portion of the first transistor T1 may overlap the storage capacitor Cst, the first holding capacitor Chold1, and the second holding capacitor Chold2. The first transistor T1 may include the driving semiconductor layer A1 and a driving gate electrode G1 on the driving semiconductor layer A1.

For example, the first transistor T1 may be disposed on the fourth insulating layer 115. FIG. 3 illustrates that the driving semiconductor layer A1 of the first transistor T1 is disposed on the fourth insulating layer 115. The driving semiconductor layer A1 may include a channel area overlapping the driving gate electrode G1, and a source area and a drain area disposed at opposite sides of the channel area. The source area and the drain area of the driving semiconductor layer A1 may be made conductive (or electrically conductive) by plasma treatment, etc.

The driving semiconductor layer A1 may include an oxide semiconductor material. For example, the driving semiconductor layer A1 may include at least one oxide selected from a group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the driving semiconductor layer A1 may include InSnZnO (ITZO) or InGaZnO (IGZO).

The driving gate electrode G1 may overlap the channel area of the driving semiconductor layer A1. The driving gate electrode G1 may include a conductive material including aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

A fifth insulating layer 116 may be disposed between the driving semiconductor layer A1 and the driving gate electrode G1. FIG. 3 illustrates that the fifth insulating layer 116 is disposed only between the driving semiconductor layer A1 and the driving gate electrode G1, but the disclosure is not necessarily limited thereto. In an embodiment, similar to another insulating layer, for example, the first insulating layer 112, the fifth insulating layer 116 may be formed to entirely cover the substrate 100. The fifth insulating layer 116 may include an inorganic insulating material such as silicon oxide, silicon nitride, or silicon oxynitride, and may have a single-layered or multilayer structure including the above-described inorganic insulating material.

A sixth insulating layer 117 may be disposed on the first transistor T1. For example, the sixth insulating layer 117 may be disposed on the driving gate electrode G1. The sixth insulating layer 117 may include an inorganic insulating material such as silicon oxide, silicon nitride, or silicon oxynitride, and may have a single-layered or multilayer structure including the above-described inorganic insulating material.

A connection conductive layer CM may be disposed on the sixth insulating layer 117. In an embodiment, the connection conductive layer CM may electrically connect the first transistor T1 and the fourth capacitor electrode CE4 to each other. For example, the connection conductive layer CM may electrically connect the driving semiconductor layer A1 of the first transistor T1 and the fourth capacitor electrode CE4 to each other. The connection conductive layer CM may include a conductive material such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

A seventh insulating layer 118 may be disposed on the connection conductive layer CM and may include an organic insulating material such as benzocyclobutene (BCB), polyimide, or hexamethyldisiloxane (HMDSO).

The driving voltage line PL may be disposed on the connection conductive layer CM. For example, the driving voltage line PL may be disposed on the seventh insulating layer 118.

An eighth insulating layer 119 may be disposed on the driving voltage line PL and may include an organic insulating material such as BCB, polyimide, or HMDSO.

The light-emitting diode LED may be disposed on the driving voltage line PL. For example, the light-emitting diode LED may be disposed on the eighth insulating layer 119. The light-emitting diode LED may include a pixel electrode 210, an emission layer 222, and an opposite electrode 230.

The pixel electrode 210 may be disposed on the eighth insulating layer 119. The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a conductive oxide layer above and/or under the above-described reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 210 may have a three-layer structure of ITO layer/Ag layer/ITO layer.

A bank layer 123 may be disposed on the pixel electrode 210. The bank layer 123 may include an opening 123OP overlapping the pixel electrode 210 and may cover an edge of the pixel electrode 210. The bank layer 123 may include an organic insulating material. In some embodiments, the bank layer 123 may include a light-transmissive organic insulating material. In an embodiment, the bank layer 123 may include an organic insulating material including a light-blocking material. In some embodiments, the bank layer 123 may include a polyimide (PI)-based binder, and a pigment in which red, green, and blue colors are mixed. Alternatively, the bank layer 123 may include a mixture of a cardo-based binder resin, a lactam black pigment and a blue pigment. Alternatively, the bank layer 123 may include carbon black. The bank layer 123 may improve a contrast of the display apparatus 1.

A spacer 125 may be disposed on the bank layer 123. The spacer 125 may include a different material from the bank layer 123. For example, the bank layer 123 includes a negative photosensitive material, while the spacer 125 includes a positive photosensitive material, and the bank layer 123 and the spacer 125 may each be formed via a separate mask process. In an embodiment, the spacer 125 may include the same material as the bank layer 123 and may be formed together with the bank layer 123 in the same mask process (for example, a halftone mask process).

The emission layer 222 may include a polymer or low-molecular-weight organic material that emits light of a certain color. The emission layer 222 may include a material that emits red light, green light, or blue light according to the light-emitting diode LED.

A functional layer may be further included under and/or above the emission layer 222. For example, a first functional layer 221 may be further included between the pixel electrode 210 and the emission layer 222, and a second functional layer 223 may be further included between the emission layer 222 and the opposite electrode 230 described below. The first functional layer 221 may include a hole transport layer and/or a hole injection layer. The second functional layer 223 may include an electron transport layer and/or an electron injection layer.

The opposite electrode 230 may include a conductive material having a low work function. For example, the opposite electrode 230 may include a transparent or semitransparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer including ITO, IZO, ZnO, or In₂O₃ on the transparent or semitransparent layer including the above-described material.

Unlike the pixel electrode 210 that is individually patterned to correspond to the light-emitting diode LED, the opposite electrode 230 may correspond to a plurality of pixel electrodes 210. For example, the pixel electrode 210 of any one light-emitting diode LED may be separated or spaced apart from the pixel electrode 210 of another light-emitting diode LED, but the opposite electrode 230 overlapping the pixel electrodes 210 may cover the plurality of pixel electrodes 210.

An encapsulation layer 300 may be disposed on the light-emitting diode LED and may include at least one inorganic encapsulation layer and at least one organic encapsulation layer. In an embodiment, FIG. 3 illustrates that the encapsulation layer 300 includes a first inorganic encapsulation layer 310, an organic encapsulation layer 320, and a second inorganic encapsulation layer 330.

Each of the first inorganic encapsulation layer 310 and the second inorganic encapsulation layer 330 may include, for example, one or more inorganic insulating materials among aluminum oxide, titanium oxide, tantalum oxide, hafnium oxide, zinc oxide, silicon oxide, silicon nitride, or silicon oxynitride. The first inorganic encapsulation layer 310 and the second inorganic encapsulation layer 330 may each be a single layer or a multilayer, each including the above-described material.

The organic encapsulation layer 320 may include a polymer-based material. The polymer-based material may include acrylic resin, epoxy-based resin, polyimide, and polyethylene. In an embodiment, the organic encapsulation layer 320 may include acrylate.

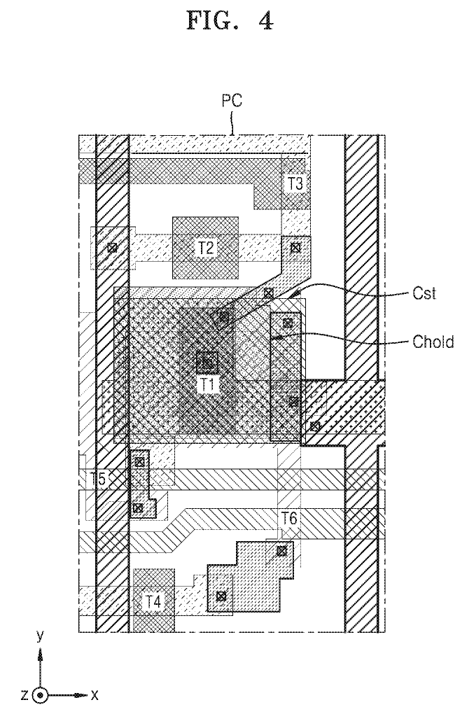

FIG. 4 is a plan view illustrating a portion of a pixel circuit of a display apparatus according to an embodiment. FIG. 4 may correspond to a planar structure of the pixel circuit PC of the display apparatus 1 described with reference to FIG. 3. For convenience of explanation, FIG. 4 illustrates some of the components of the pixel circuit PC.

Referring to FIGS. 3 and 4, the storage capacitor Cst and the holding capacitor Chold may be disposed on the substrate 100. The storage capacitor Cst and the holding capacitor Chold may overlap each other. At least a portion of the first transistor T1 may overlap each of the storage capacitor Cst and the holding capacitor Chold.

FIGS. 5 to 12 are plan views illustrating a process of forming a pixel circuit included in a display apparatus according to an embodiment.

Referring to FIG. 5, a first semiconductor layer 1100 may be disposed on the substrate 100 (see FIG. 3). For example, the first semiconductor layer 1100 may be disposed on the buffer layer 111 (see FIG. 3). The first semiconductor layer 1100 may include the first semiconductor pattern 1110 and a second semiconductor pattern 1120. The first semiconductor pattern 1110 and the second semiconductor pattern 1120 may be disposed in the same layer. For example, the first semiconductor pattern 1110 and the second semiconductor pattern 1120 may be disposed on the buffer layer 111 (see FIG. 3).

The first semiconductor pattern 1110 may have an island pattern shape in a plan view. The first semiconductor pattern 1110 may include the first capacitor electrode CE1. The first semiconductor pattern 1110 may include a semiconductor layer (hereinafter, referred to as an emission control semiconductor layer) A6 of the sixth transistor T6. For example, the first capacitor electrode CE1 and the emission control semiconductor layer A6 of the sixth transistor T6 may be integrally connected as a single uninterrupted structure.

The first capacitor electrode CE1 may be a portion that is made conductive (or electrically conductive) in at least a portion of the first semiconductor pattern 1110. For example, the first capacitor electrode CE1 may be a portion that is made conductive (e.g., electrically conductive) by performing an ion injection process, etc. on the first semiconductor pattern 1110. The first capacitor electrode CE1 may be a portion overlapping the second capacitor electrode CE2 described below with reference to FIG. 6.

The second semiconductor pattern 1120 may include a semiconductor layer (hereinafter, referred to as an operation control semiconductor layer) A5 of the fifth transistor T5.

Each of the first semiconductor pattern 1110 and the second semiconductor pattern 1120 may include amorphous silicon or may include polysilicon. For example, each of the first semiconductor pattern 1110 and the second semiconductor pattern 1120 may include polysilicon crystallized at low temperature.

Referring to FIGS. 5 and 6, a first conductive layer 1200 may be disposed on the first semiconductor layer 1100. For example, the first insulating layer 112 (see FIG. 3) may be disposed on the first semiconductor layer 1100, and the first conductive layer 1200 may be disposed on the first insulating layer 112 (see FIG. 3). The first conductive layer 1200 may include the first conductive pattern 1210, the third gate line EML, and the fifth gate line EMBL. The first conductive pattern 1210, the third gate line EML, and the fifth gate line EMBL may be disposed in the same layer. For example, the first conductive pattern 1210, the third gate line EML, and the fifth gate line EMBL may be disposed on the first insulating layer 112 (see FIG. 3).

At least a portion of the first conductive pattern 1210 may overlap the first semiconductor pattern 1110. The first conductive pattern 1210 may include the second capacitor electrode CE2. The second capacitor electrode CE2 may be a portion overlapping the first semiconductor pattern 1110. The second capacitor electrode CE2 may overlap the first capacitor electrode CE1.

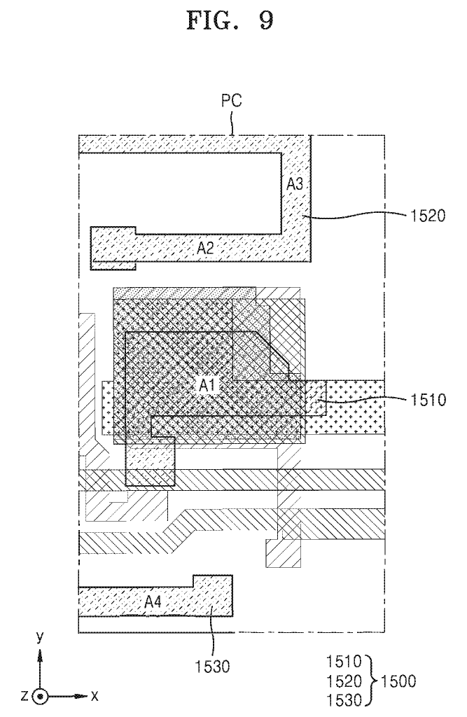

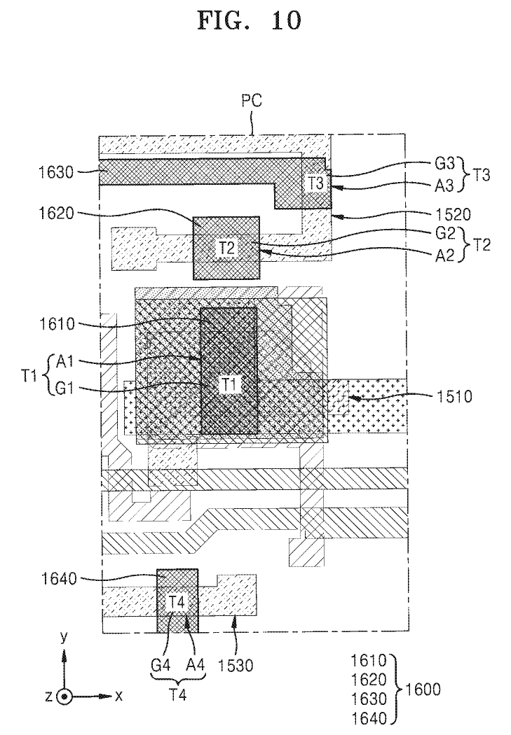

In an embodiment, the first capacitor electrode CE1 may be electrically connected to the driving gate electrode G1 of the first transistor T1 described below with reference to FIG. 10, and the second capacitor electrode CE2 may be electrically connected to the driving semiconductor layer A1 of the first transistor T1 described below with reference to FIG. 9. For example, each of the first capacitor electrode CE1 and the second capacitor electrode CE2 may be one electrode of the storage capacitor Cst. For example, the first capacitor electrode CE1 and the second capacitor electrode CE2 may form the storage capacitor Cst.

The third gate line EML may extend in a first direction (for example, an x direction). The third gate line EML may include a gate electrode overlapping the second semiconductor pattern 1120. For example, the third gate line EML may include a gate electrode (hereinafter, referred to as an operation control gate electrode) G5 of the fifth transistor T5. The operation control semiconductor layer A5 may include a channel area overlapping the operation control gate electrode G5, and a source area and a drain area disposed at opposite sides of the channel area.

The fifth gate line EMBL may extend in the first direction (for example, the x direction). The fifth gate line EMBL may include a gate electrode (hereinafter, referred to as an emission control gate electrode) G6 of the sixth transistor T6 overlapping the first semiconductor pattern 1110. The emission control semiconductor layer A6 may include a channel area overlapping the emission control gate electrode G6, and a source area and a drain area disposed at opposite sides of the channel area.

Each of the first conductive pattern 1210, the third gate line EML, and the fifth gate line EMBL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may be formed as a single layer or a multilayer, each including the above-described material.

Referring to FIGS. 6 and 7, the second conductive pattern 1310 may be disposed on the first conductive layer 1200. For example, the second insulating layer 113 (see FIG. 3) may be disposed on the first conductive layer 1200, and the second conductive pattern 1310 may be disposed on the second insulating layer 113 (see FIG. 3).

At least a portion of the second conductive pattern 1310 may overlap the first conductive pattern 1210. At least a portion of the second conductive pattern 1310 may overlap the first semiconductor pattern 1110.

The second conductive pattern 1310 may include the third capacitor electrode CE3 overlapping the second capacitor electrode CE2. At least a portion of the third capacitor electrode CE3 may overlap each of the first capacitor electrode CE1 and the second capacitor electrode CE2.

In an embodiment, the third capacitor electrode CE3 may be an electrode of a different capacitor from the first capacitor electrode CE1. For example, when the first capacitor electrode CE1 is one electrode of the storage capacitor Cst, the third capacitor electrode CE3 may be one electrode of the holding capacitor Chold. For example, when the first capacitor electrode CE1 is one electrode of the holding capacitor Chold, the third capacitor electrode CE3 may be one electrode of the storage capacitor Cst.

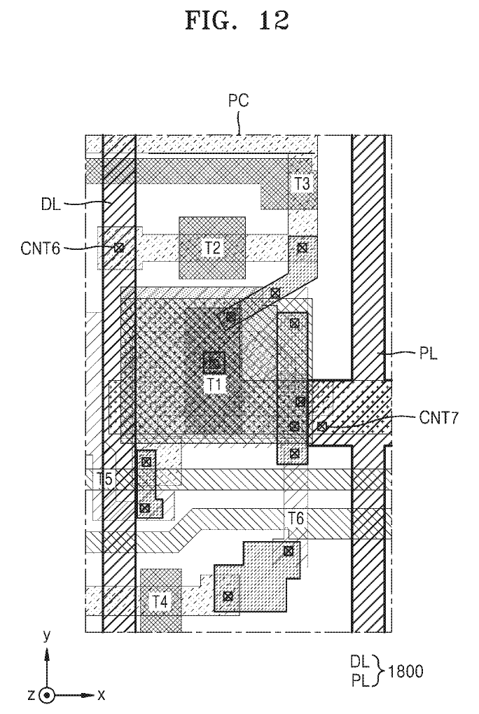

In an embodiment, the second capacitor electrode CE2 may be electrically connected to the driving semiconductor layer A1 of the first transistor T1 described below with reference to FIG. 9, and the third capacitor electrode CE3 may be electrically connected to the driving voltage line PL described below with reference to FIG. 12. For example, each of the second capacitor electrode CE2 and the third capacitor electrode CE3 may be one electrode of the holding capacitor Chold. For example, the second capacitor electrode CE2 and the third capacitor electrode CE3 may form the first holding capacitor Chold1.

The second conductive pattern 1310 may include a conductive material, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

Referring to FIGS. 7 and 8, the third conductive pattern 1410 may be disposed on the second conductive pattern 1310. For example, the third insulating layer 114 (see FIG. 3) may be disposed on the second conductive pattern 1310, and the third conductive pattern 1410 may be disposed on the third insulating layer 114 (see FIG. 3).

At least a portion of the third conductive pattern 1410 may overlap the second conductive pattern 1310. At least a portion of the third conductive pattern 1410 may overlap the first conductive pattern 1210. At least a portion of the third conductive pattern 1410 may overlap the first semiconductor pattern 1110 (see FIG. 6).

The third conductive pattern 1410 may include the fourth capacitor electrode CE4 overlapping the third capacitor electrode CE3. At least a portion of the fourth capacitor electrode CE4 may overlap each of the first capacitor electrode CE1, the second capacitor electrode CE2, and the third capacitor electrode CE3.

In an embodiment, the fourth capacitor electrode CE4 may be an electrode of a different capacitor from the first capacitor electrode CE1. For example, when the first capacitor electrode CE1 is one electrode of the storage capacitor Cst, the fourth capacitor electrode CE4 may be one electrode of the holding capacitor Chold. For example, when the first capacitor electrode CE1 is one electrode of the holding capacitor Chold, the fourth capacitor electrode CE4 may be one electrode of the storage capacitor Cst.

In an embodiment, the third capacitor electrode CE3 may be electrically connected to the driving voltage line PL described below with reference to FIG. 12, and the fourth capacitor electrode CE4 may be electrically connected to the driving semiconductor layer A1 of the first transistor T1 described below with reference to FIG. 9. For example, each of the third capacitor electrode CE3 and the fourth capacitor electrode CE4 may be one electrode of the holding capacitor Chold. For example, the third capacitor electrode CE3 and the fourth capacitor electrode CE4 may form the second holding capacitor Chold2. For example, the second capacitor electrode CE2, the third capacitor electrode CE3, and the fourth capacitor electrode CE4 may form the holding capacitor Chold.

The third conductive pattern 1410 may include a conductive material, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may have a single-layered or multilayer structure including the above-described material.

Referring to FIGS. 8 and 9, a second semiconductor layer 1500 may be disposed on the third conductive pattern 1410. For example, the fourth insulating layer 115 (see FIG. 3) may be disposed on the third conductive pattern 1410, and the second semiconductor layer 1500 may be disposed on the fourth insulating layer 115 (see FIG. 3). The second semiconductor layer 1500 may include a third semiconductor pattern 1510, a fourth semiconductor pattern 1520, and a fifth semiconductor pattern 1530. The third semiconductor pattern 1510, the fourth semiconductor pattern 1520, and the fifth semiconductor pattern 1530 may be disposed in the same layer. For example, the third semiconductor pattern 1510, the fourth semiconductor pattern 1520, and the fifth semiconductor pattern 1530 may be disposed on the fourth insulating layer 115 (see FIG. 3).

At least a portion of the third semiconductor pattern 1510 may overlap the third conductive pattern 1410. At least a portion of the third semiconductor pattern 1510 may overlap the second conductive pattern 1310. At least a portion of the third semiconductor pattern 1510 may overlap the first conductive pattern 1210. At least a portion of the third semiconductor pattern 1510 may overlap the first semiconductor pattern 1110 (see FIG. 6).

The third semiconductor pattern 1510 may have an island pattern shape in a plan view. The third semiconductor pattern 1510 may include the driving semiconductor layer A1 of the first transistor T1. At least a portion of the third semiconductor pattern 1510 may overlap each of the first capacitor electrode CE1, the second capacitor electrode CE2, and the third capacitor electrode CE3. For example, at least a portion of the driving semiconductor layer A1 may overlap each of the first capacitor electrode CE1, the second capacitor electrode CE2, and the third capacitor electrode CE3.

The fourth semiconductor pattern 1520 may include a semiconductor layer (hereinafter, referred to as a data write semiconductor layer) A2 of the second transistor T2 and a semiconductor layer (hereinafter, referred to as a compensation semiconductor layer) A3 of the third transistor T3.

The fifth semiconductor pattern 1530 may include a semiconductor layer (hereinafter, referred to as an initialization semiconductor layer) A4 of the fourth transistor T4.

Each of the third semiconductor pattern 1510, the fourth semiconductor pattern 1520, and the fifth semiconductor pattern 1530 may include an oxide semiconductor material. For example, each of the third semiconductor pattern 1510, the fourth semiconductor pattern 1520, and the fifth semiconductor pattern 1530 may include at least one oxide selected from a group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, each of the third semiconductor pattern 1510, the fourth semiconductor pattern 1520, and the fifth semiconductor pattern 1530 may include InSnZnO (ITZO) or InGaZnO (IGZO).

Referring to FIGS. 9 and 10, a second conductive layer 1600 may be disposed on the second semiconductor layer 1500. The second conductive layer 1600 may include a fourth conductive pattern 1610, a fifth conductive pattern 1620, a sixth conductive pattern 1630, and a seventh conductive pattern 1640.

The fourth conductive pattern 1610, the fifth conductive pattern 1620, the sixth conductive pattern 1630, and the seventh conductive pattern 1640 may be disposed in the same layer. For example, the fourth conductive pattern 1610, the fifth conductive pattern 1620, the sixth conductive pattern 1630, and the seventh conductive pattern 1640 may disposed on the fifth insulating layer 116 (see FIG. 3). In an embodiment, as described above with reference to FIG. 3, the fifth insulating layers 116 (see FIG. 3) respectively disposed under the fourth conductive pattern 1610, the fifth conductive pattern 1620, the sixth conductive pattern 1630, and the seventh conductive pattern 1640 may be separated from each other, but the disclosure is not necessarily limited thereto. In an embodiment, the fifth insulating layers 116 (see FIG. 3) respectively disposed under the fourth conductive pattern 1610, the fifth conductive pattern 1620, the sixth conductive pattern 1630, and the seventh conductive pattern 1640 may be integrally connected as a single uninterrupted structure.

In an embodiment, the fourth conductive pattern 1610 may have an island pattern shape. The fourth conductive pattern 1610 may include the driving gate electrode G1 of the first transistor T1 overlapping the third semiconductor pattern 1510. The driving semiconductor layer A1 may include a channel area overlapping the driving gate electrode G1, and a source area and a drain area disposed at opposite sides of the channel area.

In an embodiment, the fifth conductive pattern 1620 may have an island pattern shape. The fifth conductive pattern 1620 may include a gate electrode (hereinafter, referred to as a data write gate electrode) G2 of the second transistor T2 overlapping the fourth semiconductor pattern 1520. The data write semiconductor layer A2 may include a channel area overlapping the data write gate electrode G2, and a source area and a drain area disposed at opposite sides of the channel area.

The sixth conductive pattern 1630 may include a gate electrode (hereinafter, referred to as a compensation gate electrode) G3 of the third transistor T3 overlapping the fourth semiconductor pattern 1520. The compensation semiconductor layer A3 may include a channel area overlapping the compensation gate electrode G3, and a source area and a drain area disposed at opposite sides of the channel area.

In an embodiment, the sixth conductive pattern 1630 may have a line shape extending in the first direction (for example, the x direction). For example, the sixth conductive pattern 1630 may be a portion of the second gate line GRL.

The seventh conductive pattern 1640 may include a gate electrode (hereinafter, referred to as an initialization gate electrode) G4 of the fourth transistor T4 overlapping the fifth semiconductor pattern 1530. The initialization semiconductor layer A4 may include a channel area overlapping the initialization gate electrode G4, and a source area and a drain area disposed at opposite sides of the channel area.

The seventh conductive pattern 1640 according to an embodiment may have a line shape extending in the first direction (for example, the x direction) in an unshown area. For example, the seventh conductive pattern 1640 may be a portion of the fourth gate line GIL.

Each of the fourth conductive pattern 1610, the fifth conductive pattern 1620, the sixth conductive pattern 1630, and the seventh conductive pattern 1640 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), or another conductive material with an electrical conductivity similar to that of one or more of the above-described conductive materials, and may be formed as a single layer or a multilayer, each including the above-described material.

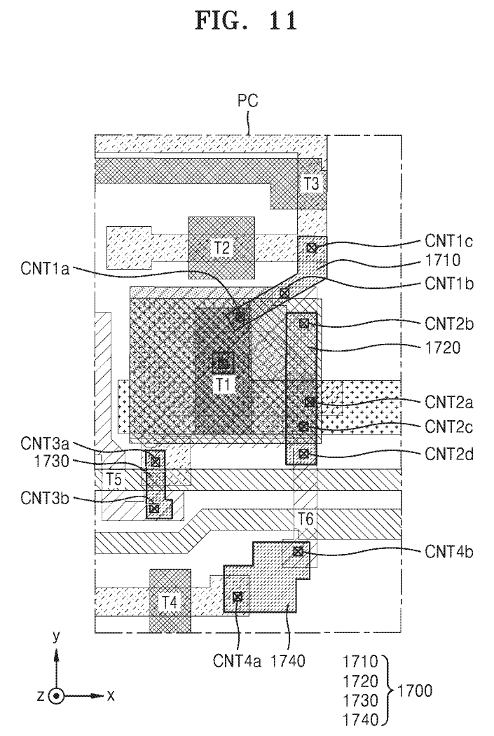

Referring to FIGS. 10 and 11, a third conductive layer 1700 may be disposed on the second conductive layer 1600. For example, the sixth insulating layer 117 (see FIG. 3) may be disposed on the second conductive layer 1600, and the third conductive layer 1700 may be disposed on the sixth insulating layer 117 (see FIG. 3). The third conductive layer 1700 may include a first connection electrode 1710, a second connection electrode 1720, a third connection electrode 1730, and a fourth connection electrode 1740. The first connection electrode 1710, the second connection electrode 1720, the third connection electrode 1730, and the fourth connection electrode 1740 may be disposed in the same layer. For example, the first connection electrode 1710, the second connection electrode 1720, the third connection electrode 1730, and the fourth connection electrode 1740 may be disposed on the sixth insulating layer 117 (see FIG. 3).

The first connection electrode 1710 may electrically connect the driving gate electrode G1 of the first transistor T1 and the first semiconductor pattern 1110 (see FIG. 6) to each other. For example, the first connection electrode 1710 may electrically connect the driving gate electrode G1 of the first transistor T1 and the first capacitor electrode CE1 (see FIG. 6) to each other. For example, the first connection electrode 1710 may be electrically connected to the driving gate electrode G1 of the first transistor T1 via a first-1 contact hole CNT1a, and may be electrically connected to the first semiconductor pattern 1110 (see FIG. 6) via a first-2 contact hole CNT1b.

The first connection electrode 1710 may electrically connect the driving gate electrode G1 of the first transistor T1 and the fourth semiconductor pattern 1520 to each other. For example, the first connection electrode 1710 may electrically connect the driving gate electrode G1 of the first transistor T1 and the data write semiconductor layer A2 of the second transistor T2 to each other. For example, the first connection electrode 1710 may electrically connect the driving gate electrode G1 of the first transistor T1 and the compensation semiconductor layer A3 of the third transistor T3 to each other. For example, the first connection electrode 1710 may be electrically connected to the driving gate electrode G1 of the first transistor T1 via the first-1 contact hole CNT1a, and may be electrically connected to the fourth semiconductor pattern 1520 via a first-3 contact hole CNT1c.

The second connection electrode 1720 may electrically connect the third semiconductor pattern 1510, the first conductive pattern 1210 (see FIG. 6), the third conductive pattern 1410 (see FIG. 8), and the first semiconductor pattern 1110 (see FIG. 5) to each other. For example, the second connection electrode 1720 may electrically connect the driving semiconductor layer A1 of the first transistor T1, the second capacitor electrode CE2 (see FIG. 6), the fourth capacitor electrode CE4 (see FIG. 8), and the emission control semiconductor layer A6 (see FIG. 6) of the sixth transistor T6 (see FIG. 6) to each other. For example, the second connection electrode 1720 may be electrically connected to the third semiconductor pattern 1510 via a second-1 contact hole CNT2a. For example, the second connection electrode 1720 may be electrically connected to the first conductive pattern 1210 (see FIG. 6) via a second-2 contact hole CNT2b. For example, the second connection electrode 1720 may be electrically connected to the third conductive pattern 1410 (see FIG. 8) via a second-3 contact hole CNT2c. For example, the second connection electrode 1720 may be electrically connected to the first semiconductor pattern 1110 (see FIG. 5) via a second-4 contact hole CNT2d. For example, the second connection electrode 1720 may be referred to as a node electrode corresponding to the second node N2 described with reference to FIG. 2.

The third connection electrode 1730 may electrically connect the third semiconductor pattern 1510 and the second semiconductor pattern 1120 (see FIG. 5) to each other. For example, the third connection electrode 1730 may electrically connect the driving semiconductor layer A1 of the first transistor T1 and the operation control semiconductor layer A5 (see FIG. 5) of the fifth transistor T5 to each other. For example, the third connection electrode 1730 may be electrically connected to the third semiconductor pattern 1510 via a third-1 contact hole CNT3a, and may be electrically connected to the second semiconductor pattern 1120 (see FIG. 5) via a third-2 contact hole CNT3b.

The fourth connection electrode 1740 may electrically connect the fifth semiconductor pattern 1530 and the first semiconductor pattern 1110 (see FIG. 5) to each other. For example, the fourth connection electrode 1740 may electrically connect the initialization semiconductor layer A4 of the fourth transistor T4 and the emission control semiconductor layer A6 (see FIG. 5) of the sixth transistor T6 to each other. For example, the fourth connection electrode 1740 may be electrically connected to the fifth semiconductor pattern 1530 via a fourth-1 contact hole CNT4a, and may be electrically connected to the first semiconductor pattern 1110 (see FIG. 5) via a fourth-2 contact hole CNT4b.

Referring to FIGS. 11 and 12, a fourth conductive layer 1800 may be disposed on the third conductive layer 1700. For example, the seventh insulating layer 118 (see FIG. 3) may be disposed on the third conductive layer 1700, and the fourth conductive layer 1800 may be disposed on the seventh insulating layer 118 (see FIG. 3). The fourth conductive layer 1800 may include the data line DL and the driving voltage line PL. The data line DL and the driving voltage line PL may be disposed in the same layer. For example, the data line DL and the driving voltage line PL may be disposed on the seventh insulating layer 118 (see FIG. 3).

The data line DL may extend in a second direction (for example, a y direction). The data line DL may be electrically connected to the fourth semiconductor pattern 1520 (FIG. 9) via a sixth contact hole CNT6. For example, the data line DL may be electrically connected to the data write semiconductor layer A2 (see FIG. 9) of the second transistor T2.

The driving voltage line PL may extend in the second direction (for example, the y direction). The driving voltage line PL may be electrically connected to the second conductive pattern 1310 (see FIG. 7) via a seventh contact hole CNT7. For example, the driving voltage line PL may be electrically connected to the third capacitor electrode CE3 to transmit the driving voltage ELVDD (see FIG. 2) to the third capacitor electrode CE3.

Referring back to FIG. 3, the eighth insulating layer 119 may be disposed on the fourth conductive layer 1800, and the light-emitting diode LED may be disposed on the eighth insulating layer 119. The light-emitting diode LED may be electrically connected to the sixth transistor T6 (see FIG. 6). For example, the light-emitting diode LED may be electrically connected to the emission control semiconductor layer A6 of the sixth transistor T6 (see FIG. 6).

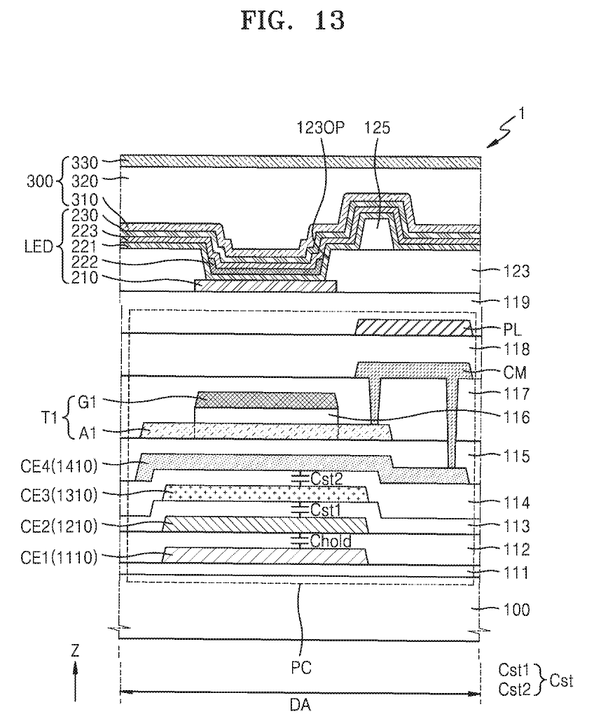

FIG. 13 is a cross-sectional view schematically illustrating a display apparatus according to an embodiment. FIG. 13 is a modified embodiment of the embodiment described with reference to FIG. 3. Modified parts shall mainly be described, and to the extent that an element is not described in detail with respect to this figure, it may be understood that the element is at least similar to a corresponding element that has been described elsewhere within the present disclosure.

Referring to FIG. 13, the holding capacitor Chold may be disposed on the substrate 100. The holding capacitor Chold may include the first capacitor electrode CE1 and the second capacitor electrode CE2. For example, the holding capacitor Chold may be disposed on the buffer layer 111.

The first capacitor electrode CE1 may be a portion of the first semiconductor pattern 1110 described with reference to FIG. 5. The second capacitor electrode CE2 may be at least a portion of the first conductive pattern 1210 described with reference to FIG. 6.

In an embodiment, the first capacitor electrode CE1 may be electrically connected to the driving voltage line PL, and the second capacitor electrode CE2 may be electrically connected to the driving semiconductor layer A1 of the first transistor T1. For example, the first capacitor electrode CE1 and the second capacitor electrode CE2 may form the holding capacitor Chold.

In an embodiment, the storage capacitor Cst may be disposed on the holding capacitor Chold. In an embodiment, the storage capacitor Cst may include a first storage capacitor Cst1 and a second storage capacitor Cst2 that overlap each other in a direction (for example, the z direction) perpendicular to a top surface of the substrate 100. For example, each of the first storage capacitor Cst1 and the second storage capacitor Cst2 may overlap the holding capacitor Chold. The first storage capacitor Cst1 may be referred to as a lower storage capacitor, and the second storage capacitor Cst2 may be referred to as an upper storage capacitor.

In an embodiment, the first storage capacitor Cst1 may include the second capacitor electrode CE2 and the third capacitor electrode CE3. For example, the second capacitor electrode CE2 may function as one electrode of the holding capacitor Chold and simultaneously may function as one electrode of the first storage capacitor Cst1.

The third capacitor electrode CE3 may be at least a portion of the second conductive pattern 1310 described with reference to FIG. 7. The fourth capacitor electrode CE4 may be at least a portion of the third conductive pattern 1410 described with reference to FIG. 8.

In an embodiment, the second storage capacitor Cst2 may include the third capacitor electrode CE3 and the fourth capacitor electrode CE4. For example, the first storage capacitor Cst1 and the second storage capacitor Cst2 may share the third capacitor electrode CE3.

In an embodiment, the second capacitor electrode CE2 may be electrically connected to the driving semiconductor layer A1 of the first transistor T1, and the third capacitor electrode CE3 may be electrically connected to the driving gate electrode G1 of the first transistor T1. For example, the second capacitor electrode CE2 and the third capacitor electrode CE3 may each be one electrode of the storage capacitor Cst and may form the first storage capacitor Cst1.

In an embodiment, the third capacitor electrode CE3 may be electrically connected to the driving gate electrode G1 of the first transistor T1, and the fourth capacitor electrode CE4 may be electrically connected to the driving semiconductor layer A1 of the first transistor T1. For example, the third capacitor electrode CE3 and the fourth capacitor electrode CE4 may each be one electrode of the storage capacitor Cst and may form the second storage capacitor Cst2.

In the embodiments described with reference to FIGS. 1 to 13, the storage capacitor Cst and the holding capacitor Chold overlap each other in a direction (for example, the z direction) perpendicular to the top surface of the substrate 100, such that the area on a plane where the components (for example, transistors, a storage capacitor, and a holding capacitor) of one pixel circuit PC are disposed may be reduced. Accordingly, the number of pixels that may be disposed per unit area increases, and thus, the resolution of the display apparatus 1 may be increased. In contrast, in the case of a comparative example in which the storage capacitor Cst and the holding capacitor Chold do not overlap each other, the area on a plane where the components of one pixel circuit PC are disposed is larger than the display apparatus 1 according to an embodiment, which may result in a decrease in resolution.

The display apparatus, according to an embodiment, may be applied to various electronic apparatuses. An electronic apparatus according to an embodiment may include the above-described display apparatus (for example, the display apparatus of FIG. 1), and may further include a module or apparatus having additional functions in addition to the display apparatus.

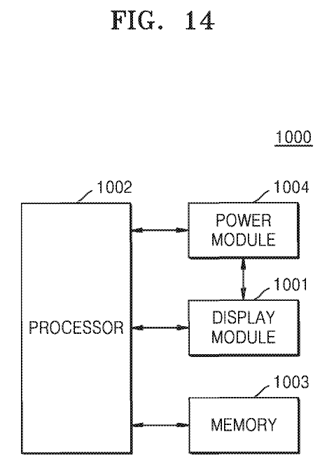

FIG. 14 is a block diagram of an electronic apparatus according to an embodiment.

Referring to FIG. 14, an electronic apparatus 1000, according to an embodiment, may include a display module 1001, a processor 1002, a memory 1003, and a power module 1004.

The processor 1002 may include at least one of a central processing unit (CPU), an application processor (AP), a graphics processing unit (GPU), a communication processor (CP), an image signal processor (ISP), and a controller.

The memory 1003 may store data information required to operate the processor 1002 or the display module 1001. When the processor 1002 executes an application stored in the memory 1003, an image data signal and/or an input control signal may be transmitted to the display module 1001, and the display module 1001 may process the received signal and output image information via a display screen.

The power module 1004 may include a power supply module, such as a power adapter or a battery apparatus, and a power conversion module that converts power supplied by the power supply module and generates power required to operate the electronic apparatus 1000.

At least one of the components of the electronic apparatus 1000 may be included in the display apparatus 1 according to the above-described embodiments. In addition, some of individual modules functionally included within one module may be included in the display apparatus 1, and the others may be provided separately from the display apparatus 1. For example, the display apparatus 1 may include the display module 1001, and the processor 1002, the memory 1003, and the power module 1004 may be provided in the form of other apparatuses within the electronic apparatus 1000 other than the display apparatus 1.

In an embodiment, the display module 1001 included in the display apparatus 1 may operate based on the image data signal and may receive the input control signal from the processor 1002.

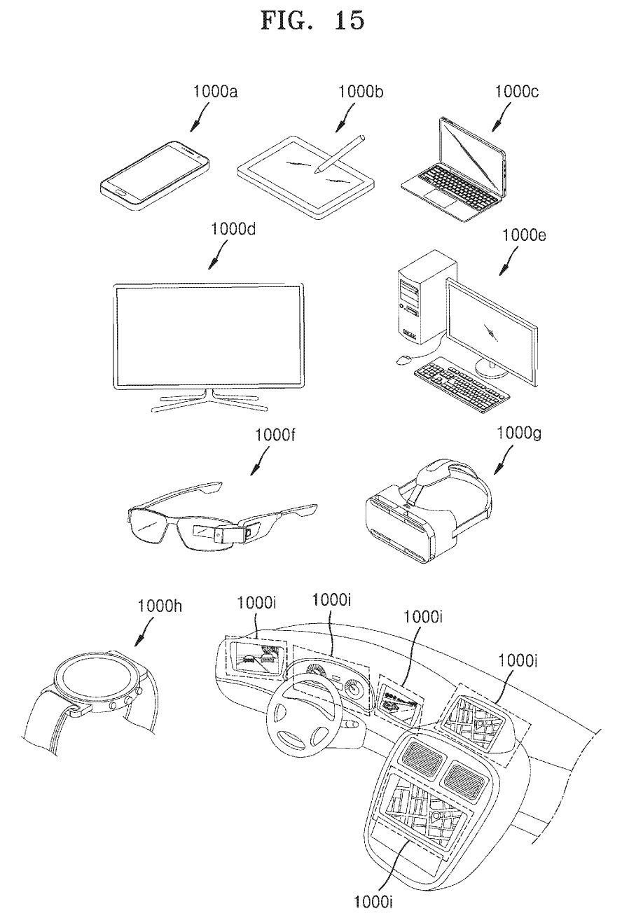

FIG. 15 are schematic views of an electronic apparatus according to various embodiments.

Referring to FIG. 15, various electronic apparatuses, to which the display apparatus according to embodiments is applied, may include not only image display electronic apparatuses, such as a smartphone 1000a, a tablet computers 1000b, a laptop/notebook computer 1000c, a TV 1000d, and a computer monitor 1000e, but also wearable electronic apparatuses including a display module, such as smart glasses 1000f, a head-mounted display 1000g, and a smart watch 1000h, as well as vehicle electronic apparatuses 1000i including a display module, such as an instrument panel of a vehicle, a center information display (CID) disposed on a center fascia or dashboard, and a room mirror display.

The display apparatus, according to an embodiment, may provide a high-quality image. Such an effect is merely an example, and the scope of the disclosure is not necessarily limited thereto.

It should be understood that embodiments described herein should be considered in a descriptive sense. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus comprising:
a first semiconductor pattern comprising a first capacitor electrode;
a first capacitor comprising the first capacitor electrode and a second capacitor electrode disposed on the first capacitor electrode;
a second capacitor comprising:
a lower capacitor comprising the second capacitor electrode and a third capacitor electrode disposed on the second capacitor electrode; and
an upper capacitor comprising the third capacitor electrode and a fourth capacitor electrode disposed on the third capacitor electrode;
a second semiconductor pattern disposed on the fourth capacitor electrode and comprising a driving semiconductor layer; and
a driving transistor comprising the driving semiconductor layer and a driving gate electrode disposed on the driving semiconductor layer.

2. The display apparatus of claim 1, wherein each of the second capacitor electrode and the fourth capacitor electrode is electrically connected to the driving semiconductor layer.

3. The display apparatus of claim 1, wherein at least a portion of the driving transistor overlaps each of the first capacitor and the second capacitor.

4. The display apparatus of claim 1, wherein the first capacitor electrode is electrically connected to the driving gate electrode, and
wherein the second capacitor electrode is electrically connected to the driving semiconductor layer.

5. The display apparatus of claim 4, further comprising:
a first connection electrode disposed on the driving gate electrode and electrically connecting the first capacitor electrode and the driving gate electrode to each other; and
a second connection electrode disposed on the driving gate electrode and electrically connecting the second capacitor electrode and the driving semiconductor layer to each other.

6. The display apparatus of claim 4, further comprising a driving voltage line carrying a driving voltage, wherein the third capacitor electrode is electrically connected to the driving voltage line.

7. The display apparatus of claim 1, wherein the second capacitor electrode is electrically connected to the driving semiconductor layer, and
wherein the third capacitor electrode is electrically connected to the driving gate electrode.

8. The display apparatus of claim 7, further comprising a driving voltage line carrying a driving voltage, wherein the first capacitor electrode is electrically connected to the driving voltage line.

9. The display apparatus of claim 1, further comprising:
an emission control line which shares a layer with the second capacitor electrode and comprises an emission control gate electrode; and
an emission control transistor comprising an emission control semiconductor layer included in the first semiconductor pattern and the emission control gate electrode.

10. The display apparatus of claim 9, further comprising a light-emitting diode electrically connected to the emission control transistor.

11. The display apparatus of claim 1, wherein the first semiconductor pattern comprises a silicon semiconductor material, and
wherein the second semiconductor pattern comprises an oxide semiconductor material.

12. A display apparatus comprising:
an emission control transistor comprising an emission control semiconductor layer and an emission control gate electrode disposed on the emission control semiconductor layer;
a first capacitor comprising a first capacitor electrode in a same layer as the emission control semiconductor layer and a second capacitor electrode disposed on the first capacitor electrode;
a second capacitor comprising:
a lower capacitor comprising the second capacitor electrode and a third capacitor electrode disposed on the second capacitor electrode; and
an upper capacitor comprising the third capacitor electrode and a fourth capacitor electrode disposed on the third capacitor electrode; and
a driving transistor comprising a driving semiconductor layer disposed on the fourth capacitor electrode and a driving gate electrode disposed on the driving semiconductor layer,
wherein each of the first capacitor and the second capacitor overlaps at least a portion of the driving transistor.

13. The display apparatus of claim 12, wherein the first capacitor electrode is electrically connected to the driving gate electrode, and
wherein each of the second capacitor electrode and the fourth capacitor electrode is electrically connected to the driving semiconductor layer.

14. The display apparatus of claim 13, further comprising:
a first connection electrode disposed on the driving gate electrode and electrically connecting the first capacitor electrode and the driving gate electrode to each other;
a second connection electrode disposed on the driving gate electrode and electrically connecting the second capacitor electrode and the driving semiconductor layer to each other; and
a driving voltage line carrying a driving voltage, wherein the third capacitor electrode is electrically connected to the driving voltage line.

15. The display apparatus of claim 12, wherein the second capacitor electrode is electrically connected to the driving semiconductor layer, and
wherein the third capacitor electrode is electrically connected to the driving gate electrode.

16. The display apparatus of claim 15, further comprising a driving voltage line carrying a driving voltage, wherein the first capacitor electrode is electrically connected to the driving voltage line.

17. The display apparatus of claim 12, further comprising:
a data write transistor comprising a data write semiconductor layer which shares a layer with the driving semiconductor layer and a data write gate electrode disposed on the data write semiconductor layer; and
a data line carrying a data signal to the data write transistor,
wherein the data write transistor is electrically connected to the driving transistor.

18. The display apparatus of claim 12, wherein the emission control semiconductor layer comprises a silicon semiconductor material, and
wherein the driving semiconductor layer comprises an oxide semiconductor material.

19. An electronic apparatus comprising a display apparatus, wherein the display apparatus comprises:
a first semiconductor pattern comprising a first capacitor electrode;
a first capacitor comprising the first capacitor electrode and a second capacitor electrode disposed on the first capacitor electrode;
a second capacitor comprising:
a lower capacitor comprising the second capacitor electrode and a third capacitor electrode disposed on the second capacitor electrode; and
an upper capacitor comprising the third capacitor electrode and a fourth capacitor electrode disposed on the third capacitor electrode;
a second semiconductor pattern disposed on the fourth capacitor electrode and comprising a driving semiconductor layer; and
a driving transistor comprising the driving semiconductor layer and a driving gate electrode disposed on the driving semiconductor layer.

20. The electronic apparatus of claim 19, further comprising:
a display module;
a processor;
a power module; and
a memory,
wherein the display apparatus comprises at least one of the display module, the processor, the power module, or the memory.
